(19) United States
(12) Patent Application Publication
(10) Pub. No.: US 2025/0247952 A1
(43) Pub. Date: Jul. 31, 2025

(54) CONTROL UNIT

(71) Applicant: MAHLE International GmbH, Stuttgart (DE)

(72) Inventors: Torbjorn Hallberg, Valencia (ES); Francisco Gonzalez Espin, La Pobla de Valbona (ES); Juan Isidro Garcia, Grado (ES)

(21) Appl. No.: 19/042,678

(22) Filed: Jan. 31, 2025

(30) Foreign Application Priority Data
Jan. 31, 2024 (DE) 102024102796.7

(51) Int. Cl. H05K 1/02; H05K 1/18

(52) U.S. Cl. CPC H05K 1/0281; H05K 1/0278; H05K 1/181; H05K 2201/10287; H05K 2201/10325; H05K 2201/2009; H05K 2201/2018

(57) ABSTRACT

A control unit for a vehicle may include an electronic assembly and at least one connector. The electronic assembly may include a printed circuit board (PCB) and at least one socket arranged on the PCB. The connector may include a plug and an external socket. The plug may be directly connected to the socket of the electronic assembly in a form-fitting and electrically conductive manner. The PCB may include a first rigid part, a second rigid part, and a flexible connecting part arranged between the first part and the second part. The socket of the electronic assembly may be arranged on the second part of the PCB. The second part of the PCB may be arranged at an angle greater than zero relative to the first part of the PCB.

### CROSS-REFERENCE TO RELATED APPLICATION

This application claims priority to German Patent Application No. DE 102024102796.7, filed on Jan. 31, 2024, the contents of which is hereby incorporated by reference in its entirety.

### TECHNICAL FIELD

The invention relates to a control unit for a vehicle with an electronic assembly and a connector which is electrically conductively connected to the electronic assembly.

### BACKGROUND

A control unit usually comprises an electronic assembly with a printed circuit board (PCB) and a connector, for example for connecting an external power source. The connector is directly connected to the PCB, wherein the connector is usually aligned perpendicular to the PCB. Due to a limited installation space for the control unit-for example in a vehicle-there is often a need to align the connector parallel to the PCB. For this purpose, for example, an internal connector can be connected between the PCB and the connector. The internal connector is disadvantageously large and requires additional installation space. Alternatively, two PCBs can be used, wherein the one PCB is arranged parallel to the connector and the other PCB is arranged perpendicular to the connector and is connected with it. The PCBs must then be connected to each other during manufacturing in a confined space and often by hand. This solution is expensive due to a complex manufacturing.

FR 3 031 802 B1 discloses a heater for a vehicle with a control unit which comprises a bent plate. EP 3 466 769 A1 discloses a PCB-structure having two sections and a flexible connecting member for connecting the two sections with each other.

### SUMMARY

It is therefore the object of the invention to provide an improved or at least alternative embodiment for a generic control unit, in which the disadvantages described above are overcome.

This object is solved according to the invention by the subject matter of the independent claim(s). Advantageous embodiments are the subject matter of the dependent claim(s).

The present invention is based on the general idea of using a bent printed circuit board instead of two printed circuit boards or an internal connector, in order to make the assembly process simpler and less expensive.

The control unit, especially an electronic control unit, according to the invention is provided i.e. designed for a vehicle. The control unit comprises an electronic assembly with a printed circuit board and at least one socket arranged on the printed circuit board. The control unit also comprises at least one connector with a plug and an external socket. The plug of the respective connector is directly connected to the respective socket of the electronic assembly in a form-fitting and electrically conductive manner. According to the invention, the printed circuit board comprises a first rigid part and a second rigid part and a flexible connecting part arranged between the two rigid parts. The second part is arranged at an angle greater than zero to the first part of the printed circuit board. The respective socket is thereby arranged in the second part of the printed circuit board.

In the control unit according to the invention, the respective connector connected to the respective socket via its plug is aligned at an angle greater than zero to the first rigid part. Accordingly, the electronic assembly can be connected to the respective connector in a space-saving manner, and the control unit as a whole can be formed in a space-saving manner. In particular, no further internal connector and no further electronic assembly are necessary. As a result, the design of the control unit and also the manufacturing process can be simplified, thereby also reducing the costs of the control unit.

The two rigid parts of the printed circuit board are flexibly connected to each other via the flexible connecting part. As a result, the printed circuit board can be bent in the connecting part in such a way that the two rigid parts are arranged at the non-zero angle to each other. The angle between the two rigid parts of the printed circuit board can be defined by an angle between the normals of the two rigid parts and/or by an angle between the normals of the respective main surfaces of the two rigid parts and/or by an angle between the respective main surfaces of the two rigid parts. The two rigid parts can be integrally with i.e. integrally formed on i.e. non-detachably connected to i.e. inseparably connected to the connecting part. In particular, the connecting part can completely cross the printed circuit board along a straight line, thereby separating the printed circuit board into the two rigid parts. The two rigid parts can in particular be rectangular.

For example, the control unit can be designed for an electronic heater and/or for an electronic control arrangement of the vehicle and/or for a vehicle-side i.e. onboard charger of a vehicle. The control unit can comprise a plurality of connectors which differ from one another and the electronic assembly can comprise a plurality of sockets which differ from one another. In particular, the control unit can comprise exactly two or exactly three or exactly four or exactly five or more connectors which differ from one another and the electronic assembly can comprise exactly two or exactly three or exactly four or exactly five or more connectors which differ from one another. If a plurality of sockets and a plurality of connectors are provided, all of the respective sockets can be arranged in the second part of the printed circuit board and all of the respective connectors can be arranged perpendicular to the second part of the printed circuit board and at the angle greater than zero to the first part of the printed circuit board.

The plug of the respective connector and the respective socket can be suitably adapted to each other i.e. can be provided to be form-fittingly and electrically connectable to each other. The respective socket and the respective connector can be provided for contacting deviating external devices. The respective connector can, for example, be a high-voltage connector for connecting an external high-voltage source or a low-voltage connector for connecting an external low-voltage source. The respective socket can accordingly be provided for connecting the high-voltage connector or the low-voltage connector.

The angle between the two rigid parts can be any. Preferably, the angle between the two rigid parts can be between 60° and 120°. Particularly preferably, the angle between the two rigid parts can be equal to 90°. In particular, the first part and the second part of the printed circuit board can be arranged at an angle equal to 90° to each other. In particular, the plug of the respective connector and the respective socket in the second part of the printed circuit board can be connected to one another in a connection direction and the first part of the printed circuit board can be aligned parallel to this connection direction. In this embodiment, the control unit can be designed particularly space-saving and the connection of an external device to the external socket of the respective connector can be carried out particularly easily.

The respective socket can be connected to the printed circuit board in a material-bonded manner, preferably by soldering. The respective socket can comprise a plurality of metallic contacts and the plug of the respective connector can comprise a plurality of metallic pins. The respective metallic pins can be shaped complementary to the respective metallic contacts. The shape of the respective socket and the plug of the respective connector can thereby be adjusted for connecting an external device to be connected to the control unit. The shape and number of the respective contacts and the respective pins can be similarly adjusted for connecting an external device to be connected to the control unit. For example, for connecting an external high voltage source, the respective socket can comprise 24 contacts and the plug of the respective connector can comprise 24 pins.

The electronic assembly can comprise at least one electrical and/or electronic component. The respective component can be, for example, an inductor and/or a capacitor and/or a transistor and/or an HP filter (HP: high-pass) and/or an LP filter (LP: low-pass) and/or a power semiconductor. All components of the electronic assembly can, for example, be arranged exclusively on the first rigid part of the printed circuit board. No electrical and/or electronic components can be arranged on the second rigid part of the printed circuit board. As a result, the second rigid part of the electronic assembly can be designed i.e. shaped smaller and more space-saving, and thus the control unit itself can be designed more space-saving. The second part of the printed circuit board can in particular be smaller in area, preferably several times smaller, than the first rigid part of the support board. The electronic assembly can comprise at least one electrical wire formed on or in the printed circuit board, and the respective component can be electrically conductively connected to the respective socket via the respective wire. For this purpose, the respective wire can bridge i.e. cross the connecting part.

The control unit can comprise a housing with an interior space accommodating the electronic assembly and with a housing wall at least partially delimiting the interior space to the outside. The respective connector can protrude through the housing wall into the interior space and be firmly fixed-for example screwed-to the housing wall. The plug of the respective connector can thereby be arranged inside the interior space of the housing and the outer socket of the respective connector can be arranged outside the interior space of the housing. The second part of the printed circuit board can thereby be arranged parallel to the housing wall and adjacent to the respective connector. In other words, the respective connector can be attached to the housing wall and projects through the housing wall. Within the housing, the plug of the respective connector can be connected the respective socket on the printed circuit board. In this case, the external socket of the respective connector can be reached from the outside in a simplified manner and an external device can be connected to the control unit from the outside via the external socket in a simplified manner.

The control unit can comprise a frame for holding the electronic assembly. The frame can be made of plastic. The frame can thereby arrange and fix the first rigid part and the second part of the printed circuit board at the angle greater than zero to each other. The frame can comprise at least one clip, wherein the first rigid part of the printed circuit board can be arranged at its edge in the clip and held in a form-fitting manner. The frame can comprise at least one elongated groove, wherein the second part of the printed circuit board can be arranged at its edge in the groove and held in a form-fitting manner. In other words, the printed circuit board i.e. the electronic assembly can be form-fittingly held in the frame. As a result, the electronic assembly can be fixed without screws and with higher tolerances, whereby the respective connector can be connected to the respective socket in a simplified manner in the manufacturing process.

In particular, the printed circuit board can be a semi-flex construction. The first rigid part of the printed circuit board and the second part of the printed circuit board can be integrally i.e.

integrally formed with the connecting part of the printed circuit board. During the fabrication, the connecting part can be formed, for example, by removing material from the printed circuit board stack up. The first rigid part and the second part of the printed circuit board can have a greater thickness than the connecting part of the printed circuit board. In particular, a thickness of the connecting part can be less than 250 μm. The printed circuit board can be bendable in the connecting part. A bending radius of the connecting part can be equal to or greater than 5 mm. For stiffening the connection part of the printed circuit board, the printed circuit board can comprise at least one stiffening strand arranged on the connection part. The stiffening strand can be formed from metal.

Further important features and advantages of the invention are apparent from the subclaims, from the drawings, and from the accompanying figure description based on the drawings.

It is understood that the above features and those to be explained below can be used not only in the combination indicated in each case, but also in other combinations or on their own, without departing from the scope of the present invention.

Preferred embodiments of the invention are shown in the drawings and will be explained in more detail in the following description, wherein identical reference signs refer to identical or similar or functionally identical components.

### BRIEF DESCRIPTION OF THE DRAWINGS

It shows, in each case schematically

FIG. 1 shows a partial view of a control unit according to the invention shown without housing;

FIG. 2 shows a partial view of the control unit of the invention shown in FIG. 1 with a housing.

### DETAILED DESCRIPTION

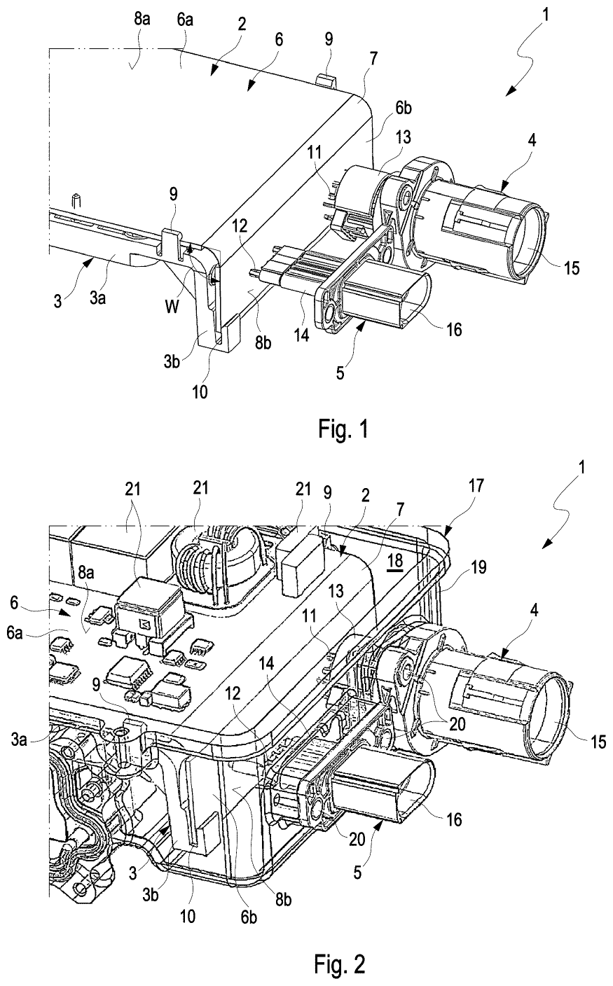

FIG. 1 shows a partial view of a control unit 1 for a vehicle according to the invention. The control unit 1 comprises an electronic assembly 2, a frame 3 supporting the electronic assembly 2 and two connectors 4 and 5. In this embodiment, connector 4 is designed for connecting an external high-voltage source and connector 5 is designed for connecting an external low-voltage source.

The electronic assembly 2 comprises a printed circuit board 6 with a first rigid part 6a, a second rigid part 6b and a flexible connecting part 7. The two parts 6a and 6b are flexibly connected to each other via the connecting part 7 and are aligned to each other at an angle W equal to 90°. The angle W is defined here by an angle between a main surface 8a of the first part 6a and a main surface 8b of the second part 6b.

The two parts 6a and 6b are arranged at the angle W by means of the frame 3. The frame 3 comprises a first section 3a for supporting the first part 6a of the printed circuit board 6 and a second section 3b for supporting the second part 6b of the printed circuit board 6. The two sections 3a and 3b are aligned perpendicularly or at an angle W equal to 90° to each other. A plurality of clips 9—only two are visible here—are formed on the first section 3a of the frame 3. The first part 6a of the printed circuit board 6 is arranged at its edge in the clips 9 and thereby is form-fittingly secured to the first section 3a of the frame 3. Two elongated grooves 10—only one visible here—are further formed on the second section 3b of the frame 3. The second part 6b of the printed circuit board 6 is arranged at its edge in the grooves 10 and thereby is form-fittingly secured to the first section 3b of the frame 3. Since the sections 3a and 3b of the frame 3 are aligned perpendicularly to one another, the two parts 6a and 6b of the printed circuit board 6 are also aligned i.e. arranged perpendicularly to one another by means of the frame 3.

The electronic assembly 2 also comprises two sockets 11 and 12. Here, the socket 11 is provided for electrical and form-fitting connection to the connector 4 and the socket 12 is provided for electrical and form-fitting connection to the connector 5. The two sockets 11 and 12 are arranged in the second part 6b of the printed circuit board 6 and soldered to it. The respective connectors 4 and 5 each comprise a plug 13 and 14 and an outer socket 15 and 16. The plugs 13 and 14 are electrically and form-fittingly connected to the respective sockets 11 and 12 and the outer sockets 15 and 16 can be electrically and form-fittingly connected to the respective external source.

In the control unit 1, the first part 6a of the printed circuit board 6 and the second part 6b of the printed circuit board 6 are arranged perpendicularly or at the angle W equal to 90° to each other. As a result, the connectors 4 and 5 are aligned perpendicularly to the second part 6b of the printed circuit board 6 and parallel to the first part 6a of the printed circuit board 6. Accordingly, the external sources can be connected to the control unit 1 parallel to the first part 6a of the printed circuit board 6. The control unit 1 is thus formed in a space-saving manner, and the connection of the external sources to the control unit 1 is simplified.

FIG. 2 shows a partial view of the control unit 1 according to the invention with a housing 17. The housing 17 comprises an interior space 18 and a housing wall 19 which partially delimits the interior space 18 from the outside. The electronic assembly 2 and the frame 3 are arranged in the interior space 18 and are partially protected from the outside by the housing wall 19. The respective connectors 4 and 5 protrude through the housing wall 19 into the interior space 18 and are firmly connected, for example screwed, to the housing wall 19 at connection points 20. Thereby, the plugs 13 and 14 of the respective connectors 4 and 5 are arranged inside the interior space 18 and the outer sockets 15 and 16 of the respective connectors 4 and 5 are arranged outside the interior space 18. Expediently, the second part 6b is aligned parallel and spaced apart and adjacent to the housing wall 19 so that a connection between the sockets 12 and 13 and the plugs 13 and 14 of the respective connectors 4 and 5 is possible.

FIG. 2 also shows electrical and/or electronic components 21 of the electronic assembly 2. The components 21 can be, for example, a coil and/or a capacitor and/or a transistor and/or an HP filter and/or an LP filter and/or a power semiconductor. The respective components 21 are suitably electrically conductively connected to each other and to the respective sockets 11 and 12. For this purpose, the electronic assembly 2 comprises a plurality of electrical wires-not visible here—which are formed on or in the printed circuit board 6. Thereby, at least some wires bridge the connection part 7 of the printed circuit board 6 and connect the respective components 21 and the respective sockets 11 and 12 in an electrically conductive manner.

In this case, all components 21 are arranged exclusively in the first part 6a of the printed circuit board 6 and the sockets 11 and 12 are arranged exclusively in the second part 6b of the printed circuit board 6. As a result, the second part 6b of the printed circuit board 6 can be smaller in area than the first part 6a and the control unit 1 can be designed more space-saving. Furthermore, the connection of the respective components 21 to each other can be simplified.

Various examples/embodiments are described herein for various apparatuses, systems, and/or methods. Numerous specific details are set forth to provide a thorough understanding of the overall structure, function, manufacture, and use of the examples/embodiments as described in the specification and illustrated in the accompanying drawings. It will be understood by those skilled in the art, however, that the examples/embodiments may be practiced without such specific details. In other instances, well-known operations, components, and elements have not been described in detail so as not to obscure the examples/embodiments described in the specification. Those of ordinary skill in the art will understand that the examples/embodiments described and illustrated herein are non-limiting examples, and thus it can be appreciated that the specific structural and functional details disclosed herein may be representative and do not necessarily limit the scope of the embodiments.

Reference throughout the specification to “examples, “in examples,” “with examples,” “various embodiments,” “with embodiments,” “in embodiments,” or “an embodiment,” or the like, means that a particular feature, structure, or characteristic described in connection with the example/embodiment is included in at least one embodiment. Thus, appearances of the phrases “examples, “in examples,” “with examples,” “in various embodiments,” “with embodiments,” “in embodiments,” or “an embodiment,” or the like, in places throughout the specification are not necessarily all referring to the same embodiment. Furthermore, the particular features, structures, or characteristics may be combined in any suitable manner in one or more examples/embodiments. Thus, the particular features, structures, or characteristics illustrated or described in connection with one embodiment/example may be combined, in whole or in part, with the features, structures, functions, and/or characteristics of one or more other embodiments/examples without limitation given that such combination is not illogical or non-functional. Moreover, many modifications may be made to adapt a particular situation or material to the teachings of the present disclosure without departing from the scope thereof.

It should be understood that references to a single element are not necessarily so limited and may include one or more of such element. Any directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of examples/embodiments.

“One or more” includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first element could be termed a second element, and, similarly, a second element could be termed a first element, without departing from the scope of the various described embodiments. The first element and the second element are both elements, but they are not the same element.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the phrase “at least one of” followed by successive elements separate by the word “and” (e.g., “at least one of A and B”) is to be interpreted the same as “and/or” and as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Joinder references (e.g., attached, coupled, connected, and the like) are to be construed broadly and may include intermediate members between a connection of elements, relative movement between elements, direct connections, indirect connections, fixed connections, movable connections, operative connections, indirect contact, and/or direct contact. As such, joinder references do not necessarily imply that two elements are directly connected/coupled and in fixed relation to each other. Connections of electrical components, if any, may include mechanical connections, electrical connections, wired connections, and/or wireless connections, among others. Uses of “e.g.” and “such as” in the specification are to be construed broadly and are used to provide non-limiting examples of embodiments of the disclosure, and the disclosure is not limited to such examples.

While processes, systems, and methods may be described herein in connection with one or more steps in a particular sequence, it should be understood that such methods may be practiced with the steps in a different order, with certain steps performed simultaneously, with additional steps, and/or with certain described steps omitted.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

All matter contained in the above description or shown in the accompanying drawings shall be interpreted as illustrative only and not limiting. Changes in detail or structure may be made without departing from the present disclosure.

1. A control unit for a vehicle, comprising:
an electronic assembly including:
a printed circuit board; and
at least one socket arranged on the printed circuit board;
at least one connector including:
a plug; and
an external socket;
the plug of the at least one connector directly connected to the at least one socket of the electronic assembly in a form-fitting and electrically conductive manner;
the printed circuit board including:
a first rigid part;
a second rigid part; and
a flexible connecting part arranged between the first part and the second part;
wherein the at least one socket is arranged in the second part of the printed circuit board; and
wherein the second part of the printed circuit board is arranged at an angle greater than zero relative to the first part of the printed circuit board.

2. The control unit according to claim 1, wherein:
the plug and the at least one socket in the second part of the printed circuit board are connected to one another in a connection direction; and
the first part of the printed circuit board is aligned parallel to the connection direction.

3. The control unit according to claim 1, wherein the at least one socket is connected to the printed circuit board in a material-bonded manner.

4. The control unit according to claim 1, wherein:
the electronic assembly further includes i) at least one electronic component and ii) at least one electrical wire formed on and/or in the printed circuit board; and
the at least one electronic component is electrically conductively connected to the at least one socket via the at least one electrical wire.

5. The control unit according to claim 1, wherein the second part of the printed circuit board is smaller in area than the first part of the printed circuit board.

6. The control unit according to claim 1, further comprising a housing, wherein:
the housing includes:
an interior space accommodating the electronic assembly; and
a housing wall at least partially delimiting the interior space to an outside;
the at least one connector protrudes through the housing wall into the interior space and is fixed to the housing wall;
the plug is arranged inside the interior space of the housing and the external socket is arranged outside the interior space of the housing; and
the second part of the printed circuit board is arranged parallel to the housing wall and adjacent to the at least one connector.

7. The control unit according to claim 1, further comprising a frame arranging and fixing the first part of the printed circuit board and the second part of the printed circuit board at the angle greater than zero.

8. The control unit according to claim 7, wherein the frame includes at least one clip in which an edge of the first part of the printed circuit board is arranged and held in a form-fitting manner.

9. The control unit according to claim 1, wherein the printed circuit board is a semi-flex plate.

10. The control unit according to claim 1, wherein:
the at least one connector is a high-voltage connector for connecting an external high-voltage source and the at least one socket is configured for connecting the high-voltage connector; and/or
the at least one connector is a low-voltage connector for connecting an external low-voltage source and the at least one socket is configured for connecting the low-voltage connector.

11. The control unit according to claim 1, wherein the control unit is provided for:
an electronic heater of the vehicle;
an electronic control arrangement of the vehicle; and/or
a vehicle-side charger of the vehicle.

12. The control unit according to claim 1, wherein the angle greater than zero is 90°.

13. The control unit according to claim 3, wherein the at least one socket is soldered to the printed circuit board.

14. The control unit according to claim 4, wherein the at least one electronic component includes a coil, a capacitor, a transistor, an HP filter, an LP filter, and/or a power semiconductor.

15. The control unit according to claim 1, wherein all electronic components of the electronic assembly are arranged exclusively on the first part of the printed circuit board.

16. The control unit according to claim 1, wherein no electronic components of the electronic assembly are arranged on the second part of the printed circuit board.

17. The control unit according to claim 7, wherein the frame includes at least one elongated groove in which an edge of the second part of the printed circuit board is arranged and held in a form-fitting manner.

18. The control unit according to claim 8, wherein the frame includes at least one elongated groove in which an edge of the second part of the printed circuit board is arranged and held in a form-fitting manner.

19. The control unit according to claim 1, wherein:
the first part, the second part, and the connecting part of the printed circuit board are integrally connected to one another;
the first part and the second part of the printed circuit board have a greater thickness than the connecting part of the printed circuit board; and
the connecting part of the printed circuit board has a thickness of 250 μm or less.

20. The control unit according to claim 1, wherein the printed circuit board further includes at least one metal stiffening strand arranged on and stiffening the connecting part of the printed circuit board.
